(19) United States
(12) Patent Application Publication
(10) Pub. No.: US 2026/0221171 A1
(43) Pub. Date: Jul. 30, 2026

(54) METHODS AND APPARATUS FOR CONTROLLING DISTINCT MEMORY DEVICES WITH A CONTROLLER

(71) Applicant: Intel Corporation, Santa Clara, CA (US)

(72) Inventors: Christopher P. MOZAK, Portland, OR (US); Aaron MARTIN, El Dorado Hills, CA (US); James Alexander MCCALL, Portland, OR (US); Alex Peter THOMAS, Folsom, CA (US)

(21) Appl. No.: 19/629,008

(22) Filed: Mar. 26, 2026

(51) Int. Cl. G11C 7/10; G11C 7/22

(52) U.S. Cl. CPC G11C 7/1069; G11C 7/1066; G11C 7/222

(57) ABSTRACT

An apparatus includes: a memory controller comprising a data interface and a read data strobe input; a first memory device and a second memory device, each having respective data lines coupled to the data interface of the memory controller; and a read data strobe line coupling a read data strobe output of one of the first and second memory devices to the read data strobe input of the memory controller, wherein the memory controller is configured to sample data received from both the first memory device and the second memory device based on a read data strobe signal received at the read data strobe input.

### BACKGROUND

Modern computing workloads, including computation-intensive applications such as artificial intelligence inference and training, have driven sustained growth in demand for memory capacity. Memory subsystems are increasingly required to serve larger data sets within the physical and electrical constraints of a given platform, placing pressure on memory architects to increase the number of memory devices that communicate over a single memory controller interface. One approach to increasing memory capacity is to increase the number of memory devices coupled to a given memory controller channel, allowing aggregate storage capacity to grow without requiring changes to the fundamental channel architecture.

A memory controller physical interface, however, is typically designed around a fixed set of signal connections, such as data lines, clock lines, command and address lines, and chip select lines, that collectively define the channel configuration. Designing a new physical interface to natively accommodate additional memory devices can entail substantial research and development investment, increase silicon area and pin count, raise power consumption, and risks breaking compatibility with the physical interface used across other product variants that do not require the additional capacity.

A more efficient path may be to configure multiple memory devices to communicate with an existing memory controller interface that was originally designed for fewer devices, preserving the physical interface architecture while still achieving the desired capacity increase. This approach can allow a single memory subsystem design to serve an entire family of products spanning different capacity points, which may result in avoiding the cost and schedule impact of a ground-up physical interface redesign for each capacity variant.

### BRIEF DESCRIPTION OF FIGURES

In the drawings, like reference characters generally refer to the same parts throughout the different views. The drawings are not necessarily to scale, emphasis instead generally being placed upon illustrating the principles of the disclosure. In the following description, various aspects of the disclosure are described with reference to the following drawings, in which:

FIG. 1 illustrates a block diagram of an example computing system;

FIG. 2 illustrates a block diagram of an example host apparatus and a memory device in accordance with various aspects described herein;

FIG. 3 illustrates a schematic diagram of an example apparatus 300 in accordance with various aspects described herein;

FIG. 4 illustrates a schematic representation of an example semiconductor wafer in accordance with various aspects described herein;

FIG. 5 shows an example of a method.

### DESCRIPTION

The present disclosure relates to memory systems, and more particularly to apparatus including a memory controller and a plurality of memory devices communicating over a data interface. Aspects may include a read data strobe signal generated by a memory device serving as a timing reference for sampling data received at the memory controller from the memory devices.

In memory systems where multiple memory devices are coupled to a single memory controller interface as described herein, the memory controller requires to determine the sampling instant for data arriving from each memory device during read operations. Memory devices coupled to a common controller interface may exhibit different internal signal propagation characteristics arising from process, voltage, and temperature variations, causing data from different devices to arrive at the controller at subtly different times relative to a common timing reference. Modern computing workloads, including computation-intensive applications such as artificial intelligence inference and training, have driven sustained growth in demand for memory capacity, and the need to support increasing numbers of memory devices per channel makes this timing challenge increasingly consequential.

One of the conventional approaches to ensure accurate data sampling in systems with multiple memory devices may be to provide each memory device with a dedicated read data strobe output that is individually connected to a corresponding strobe input at the memory controller. By providing a per-device strobe connection, the memory controller can independently track the timing of data arriving from each device, compensating for device-specific propagation delays and environmental variations that affect each device independently. While this approach achieves reliable per-device timing accuracy, the approach imposes significant costs.

Each additional strobe connection would require dedicated signal lines routed between the memory devices and the memory controller, increasing pin count at both the device and the controller physical interface. The increased number of strobe inputs requires corresponding receive circuitry within the physical interface layer of the memory controller, adding area, power consumption, and design complexity. Furthermore, a physical interface designed to accommodate the full complement of per-device strobe connections for a high-capacity configuration may be incompatible with physical interfaces used in lower-capacity product variants, undermining the goal of maintaining a common memory subsystem across a family of products. There is a need for an approach in which a reduced number of read data strobe connections serves multiple memory devices, enabling increased memory capacity without the pin count, power, and compatibility costs associated with per-device strobe routing.

As hinted above, the demand for increased memory capacity in computation-intensive systems has created a need to support higher numbers of memory devices per memory channel. Conventional approaches to increasing capacity, such as redesigning the memory controller to support additional ranks or redesigning the physical interface to natively accommodate additional device types, require substantial engineering investment, increase silicon area and pin count, raise power consumption, and break compatibility with physical interface designs used across lower-capacity product variants in the same product family.

Various aspects described herein may address this problem by providing an apparatus in which two memory devices, each having a data width narrower than the data width of the memory controller's data interface, are coupled to a single memory controller. These two memory devices may collectively serve the full width of the controller's data interface. The memory controller and its associated physical interface may require only modest logical modifications relative to a baseline single-device configuration, which results in enabling a single memory subsystem design to serve an entire product family spanning multiple capacity points without a ground-up redesign of the physical interface layer.

When two memory devices are coupled to a single memory controller interface in place of a single wider-width device, the memory controller's shared signal lines, including the write clock line, the command and address bus, the chip select lines, and the system clock line, may be each loaded by two memory devices rather than one. This results in increasing the capacitive load presented to each of these signal lines. The increased loading introduces signal integrity challenges that, if unaddressed, may degrade the achievable data rate or cause timing violations on the affected signal lines. Various aspects described herein may involve providing a write clock line with a controlled impedance profile and electromagnetic isolation configured to mitigate the signal integrity impact of the doubled capacitive loading. By employing two-cycle command timing on the command and address bus, the signal integrity requirements can be relaxed on that bus in a manner consistent with existing memory device specifications. These measures can collectively allow the shared signal lines to operate reliably at high data rates despite the increased loading imposed by the dual-device configuration, without requiring additional signal lines or changes to the physical interface pin assignment.

In a memory system, two memory devices may be coupled to a single memory controller interface. In such a configuration, the conventional approach may include providing each memory device with a dedicated read data strobe output connected to the memory controller. This approach requires additional strobe signal lines, additional strobe receive circuitry within the physical interface, and increased pin count at both the memory devices and the memory controller. These additions increase the cost, power consumption, and area of the physical interface and break compatibility with physical interface designs used in single-device configurations.

Various aspects described herein may involve providing an apparatus in which a read data strobe line couples a read data strobe output of only one of the two memory devices to the read data strobe input of the memory controller. In this configuration, the memory controller may be configured to sample data received from both the first memory device and the second memory device based on the single read data strobe signal received at the strobe input. This arrangement can eliminate the need for a dedicated per-device strobe connection, preserving the strobe pin assignment of a single-device configuration while still enabling the memory controller to correctly capture data from both memory devices.

When two memory devices share a single read data strobe connection in the configuration described above, differences in the internal signal propagation delays of the two memory devices can cause their respective data outputs to arrive at the memory controller at different times relative to the shared strobe signal. In such an arrangement, the memory controller cannot rely on the shared strobe to simultaneously represent the correct sampling reference for both devices, because the device whose strobe output is not connected may have a different tWCK2DQO delay than the device whose strobe is used. If left uncompensated, this inter-device delay difference causes sampling errors for data received from the device whose strobe is not connected to the controller.

Various aspects provided herein can address this delay issue by providing timing compensation circuitry within the memory controller. The timing compensation circuitry may determine and apply a respective sampling timing offset for data received from each of the two memory devices relative to the shared read data strobe signal. The respective sampling timing offset may be based on the offset bounded by a predetermined maximum number of unit intervals of a data clock signal. The timing compensation circuitry can select, for each memory device, a respective sampling edge polarity and a respective phase delay, which can result in providing two independent degrees of freedom for aligning the sampling point of each device to the center of its respective data eye.

The effectiveness of the timing compensation circuitry in compensating for inter-device delay differences depends on the magnitude of the delay mismatch between the two memory devices remaining within the compensation range supported by the circuitry. Memory device specifications can define a wide range of permissible tWCK2DQO delay values across the device population, and pairs of memory devices drawn at random from the full population may exhibit delay mismatches that exceed the compensation range. Various aspects provided herein may allow memory devices that have mutually matched internal signal propagation delays within a specified tolerance expressed in unit intervals of the data clock, so that the inter-device delay mismatch for any paired set of devices remains within the range that the timing compensation circuitry can accommodate. In some examples, matched devices may be selected based on timing signals generated by delay measurement circuits integrated within each memory device, based on physical proximity of die locations on a common semiconductor wafer, or based on matching of delay sensitivity to temperature and voltage variations, individually or in combination.

In some aspects, the data lines of the two memory devices must be coupled to the memory controller's data interface in a manner that allows the controller to address each device's data contribution independently and collectively serve the full interface width. Where two memory devices each having a data width narrower than the memory controller's data interface are used, each device's data lines may be coupled to a respective non-overlapping portion of the controller's data interface, so that the two devices collectively span the full data interface width. In some examples, each of the two memory devices has a data width equal to half the data width of the memory controller's data interface, such that the two devices together exactly fill the controller's data interface without redundancy or gap, and the controller's read and write datapaths can operate across the full interface width using data contributions from both devices in every transfer operation.

A memory controller may refer to a circuit configured to manage read and write operations to one or more memory devices. The memory controller may issue commands that direct memory devices to perform storage and retrieval operations, control the timing of data transfers, and process data received from memory devices during read operations. A memory device may be an integrated circuit including an array of storage cells that are accessible via a data interface. Memory devices retain data in addressable storage locations and transfer data to and from a memory controller in response to commands received over a command and address bus. A memory controller and one or more memory devices may communicate over a channel, which includes a set of signal connections, which may include data lines, strobe lines, clock lines, command and address lines, and chip select lines, through which the memory controller and the memory devices exchange data, commands, and timing signals. A memory subsystem may include one or more channels, each channel supporting one or more memory devices.

A data interface may include the set of signal lines through which data can be transferred between a memory controller and a memory device. Data lines may be the individual signal conductors within the data interface, which the data lines carry data bits between the memory controller and the memory devices. The data lines may be designated via “DQ”. The data interface has a data width corresponding to the number of data lines it includes, which corresponds the number of data bits transferred in parallel during each data transfer operation.

A memory device coupled to the data interface may have a data width equal to the number of data lines the memory device drives or receives. In certain memory systems, a plurality of memory devices may collectively serve a single data interface of the memory controller, with each memory device contributing a portion of the total data width. By way of example, in low-power double data rate (LPDDR) memory systems, data widths of x12 and x6 are defined, where a x12 device drives twelve data lines and a x6 device drives six data lines. In various examples provided herein, a memory controller having a x12 data interface may be served by a single x12 memory device or by two x6 memory devices whose data lines are coupled to respective portions of the controller's data interface.

Various aspects described herein may refer to a read data strobe (RDQS). A RDQS is a timing reference signal output by a memory device during read operations. The memory controller may use the read data strobe to determine the correct sampling instants for incoming data received on the data lines. The read data strobe is typically edge-aligned with the data outputs of the memory device, such that transitions on the data lines occur in a defined temporal relationship to transitions on the read data strobe.

In some aspects, the memory controller applies an internal delay to the received read data strobe signal to shift the sampling point toward the center of the data eye, maximizing the timing margin for data capture. The read data strobe may typically be implemented as a differential signal pair, which are designated RDQS_P and RDQS_N, to improve noise immunity and reduce susceptibility to common-mode interference. In conventional memory systems, each memory device may have a dedicated read data strobe output that is connected to a corresponding strobe input at the memory controller, enabling the controller to independently track the timing of data from each device. Various aspects described herein may involve an apparatus in which a single read data strobe output from one of a plurality of memory devices is connected to the memory controller's strobe input and used as the timing reference for sampling data from all of the plurality of memory devices.

A write clock (WCK) is a clock signal forwarded from the memory controller to the memory devices over a write clock line. The memory devices use the write clock as a timing reference for data output during read operations and for data input sampling during write operations. The write clock is typically implemented as a differential signal pair, designated WCK_P and WCK_N, and operates at the data rate frequency such that each edge of the write clock corresponds to one unit interval of the data transfer. The write clock may be distributed from the memory controller to one or more memory devices, and in systems where two memory devices share a write clock line, the write clock signal is routed from the memory controller's write clock output to the clock inputs of both memory devices. When a write clock line is loaded by multiple memory devices, the capacitive loading on the line may be increased relative to a single-device configuration, which can affect signal integrity and must be accounted for in the physical design of the write clock trace.

Signal propagation delays within a memory device may describe the internal timing relationships between signals at the device's external interface. A first delay, designated tWCK2DQO, is the delay from a write clock edge at the memory device's clock input to a data output transition at the memory device's data output pins. The tWCK2DQO delay may represent the time required for the memory device's internal read datapath to propagate data from the storage array to the output drivers in response to a write clock edge, and is specified as a range of 600 to 1600 picoseconds in certain memory device specifications.

A second delay, designated tWCK2DQI, is the delay from a data strobe input transition to the data input sampling point within the memory device during write operations, and may be specified as a range of 250 to 600 picoseconds. Both tWCK2DQO and tWCK2DQI may be device-specific values that vary across individual memory devices due to process, voltage, and temperature variations. In various aspects described herein, when two memory devices share a single read data strobe connection, differences in the tWCK2DQO values of the two devices may cause their data outputs to arrive at the memory controller at different times relative to the shared strobe signal. A unit interval (UI) is a timing metric equal to the duration of one data bit period at the data clock frequency, and is used throughout this disclosure to express timing tolerances and offsets in a frequency-normalized manner.

A command and address bus (CA) is the set of signal lines over which the memory controller transmits commands and address information to the memory devices. A chip select (CS) signal is a signal line used by the memory controller to select a specific memory device or rank for a command or data transfer operation. A system clock (CK) is a differential clock signal, designated CK_P and CK_N, forwarded from the memory controller to the memory devices to serve as a reference for command and address timing. The system clock operates at half the frequency of the write clock, such that one system clock cycle corresponds to two write clock cycles. Commands may be transferred using 1N timing, in which one command is transmitted per system clock cycle, or 2N timing, in which one command is transmitted every two system clock cycles. The use of 2N command timing can relax the signal integrity requirements on the command and address bus relative to 1N timing, accommodating the increased capacitive loading that arises when two memory devices share a common command and address bus.

A physical interface (PHY), as described herein, is the circuit block within the memory controller that may implement the electrical interface to the memory channel, including transmit drivers, receive samplers, delay-locked loops, and associated timing and calibration circuits. The PHY may be configured to translate digital data and control signals from the memory controller's digital logic into the analog signals required by the memory channel, and to convert incoming analog signals from the memory devices into digital signals for processing by the controller's read datapath. A memory subsystem (MemSS) comprises the memory controller, the PHY, and associated logic circuits that collectively implement a complete memory interface. A single MemSS design may be instantiated across multiple product variants (stock-keeping units (SKUs)), that differ in memory capacity or configuration. The ability of a single MemSS to serve multiple product SKUs without redesign is a significant practical advantage, as it reduces development cost, verification effort, and time to market across the product family.

A rank as described herein (i.e. a memory rank), may refer to a group of memory devices or memory device portions that respond simultaneously to a single chip select signal, collectively driving or receiving the full width of the data interface during a single data transfer operation. A memory device may include one or more ranks, with each rank independently addressable by the memory controller via respective chip select signals. Burst length may refer to the number of data bits transferred on a single data line during a single read or write operation, and it corresponds to the length of a data packet, i.e. the sequence of data bits transferred across the data interface in response to a single read or write command. In systems where a memory controller designed for a wider data interface is served by memory devices having a narrower data width, the burst length may be adapted relative to the nominal burst length of the controller's interface to maintain the same total number of bits per data packet while accommodating the reduced number of data lines per device.

Signal integrity herein may refer to the fidelity with which an electrical signal is transmitted from a source to a receiver. The term signal integrity may encompass the degree to which the signal waveform at the receiver accurately represents the intended signal. Key signal integrity metrics include eye height, the vertical opening of the signal eye diagram representing the noise margin, and eye width, the horizontal opening representing the timing margin. Impedance herein refers to the opposition to alternating current flow presented by a signal trace, and is characterized by a characteristic impedance value that depends on the trace geometry and surrounding dielectric. An impedance transition may refer to a discontinuity in the characteristic impedance of a signal path, such as occurs at a branch point where a signal trace divides to reach two or more destinations, and can cause signal reflections that degrade signal integrity.

Crosstalk refers to the unwanted coupling of a signal from one conductor to an adjacent conductor due to capacitive or inductive coupling, and is a significant concern when multiple high-frequency signal traces are routed in proximity. Electromagnetic isolation refers to the use of physical separation, shielding conductors, or controlled routing geometries to reduce crosstalk between signal traces. In the context of the present disclosure, controlled impedance profiling and electromagnetic isolation of write clock traces may be used to mitigate the signal integrity impact of increased capacitive loading when a write clock line drives multiple memory devices.

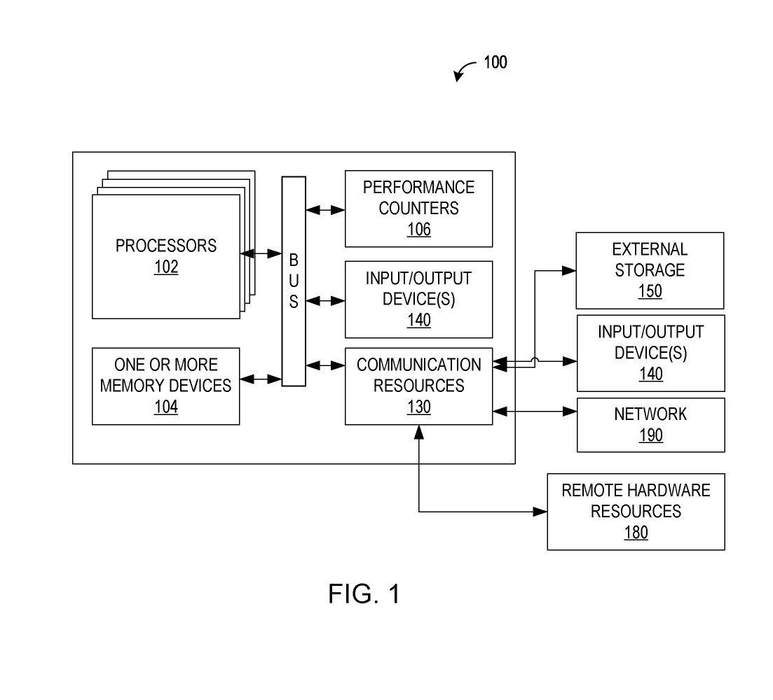

FIG. 1 illustrates a block diagram of an example computing system 100 in accordance with various aspects described herein. The computing system 100 typically includes a system of interconnected hardware and software resources configured to execute instructions, process data, and manage the allocation of computational capabilities. The computing system 100 may be a server, a workstation, a cluster of servers, a data center, a mobile computing platform, a client computing device, or a cloud computing infrastructure. External storage 150, network 190, external input and output devices 140, and remote hardware resources 180 connect to the hardware resources via the communication resources 130 and input and output devices 140.

The computing system 100 generally includes one or more processors 102, one or more memory devices 104, a bus, communication resources 130, and one or more input/output devices 140. The processors 102 represent the computational core of the computing system 100 and each processor among the processors 102 may integrate a cache hierarchy and a memory controller interface through which the processor 102 initiates memory transactions directed to the one or more memory devices 104. The memory controller interface includes a physical interface layer that includes the signal connections. The physical interface layer may further facilitate timing relationships, and implement data transfer protocols through which the processor 102 communicates with the one or more memory devices 104. The capacity of the memory subsystem accessible through this interface may be based on in part the number and configuration of memory devices 104 coupled to the interface.

The processors 102 may include one or more physical processing units. Each processing unit among the processors 102 may constitute a central processing unit, a microprocessor, a digital signal processor, or a graphics processing unit configured to perform general-purpose computing tasks. The processors 102 may include, for example, one or a combination of: a central processing unit (CPU), a reduced instruction set computing (RISC) processor, a complex instruction set computing (CISC) processor, a graphics processing unit (GPU), a DSP, an ASIC, an FPGA, a microprocessor or controller, a multi-core processor, a multithreaded processor, an ultra-low voltage processor, an embedded processor, an xPU, a data processing unit (DPU), an Infrastructure Processing Unit (IPU), a network processing unit (NPU), another processor (including any of those discussed herein), and/or any suitable combination thereof.

Each processor among the processors 102 communicates with the one or more memory devices 104 through a memory controller that manages command scheduling, address mapping, rank selection, refresh management, and coordination of data transfers, incorporating timing control logic that enforces the temporal constraints imposed by the memory interface specification. The memory controller may include a data interface having a designated data width and a read data strobe input through which the memory controller receives timing reference signals from the one or more memory devices 104, using those timing reference signals to determine the correct sampling instants for data received on the data interface.

In some examples, the one or more processors 102 may execute instructions (e.g., non-transitory computer-readable instructions). Instructions may include software, program code, application(s), applet(s), an app(s), firmware, microcode, machine code, and/or other executable code for causing at least any one of the processors 102 to perform a method. The instructions may reside, completely or partially, within at least one of the processors 102 (e.g., within the processor's cache memory), the memory devices 104, or any suitable combination thereof. Furthermore, any portion of the instructions may be transferred to the computing system 100 from any combination of the input and/or output devices 140 or the external storage 150.

The one or more memory devices 104 provide the main storage for data and instructions that are actively used by the processors 102. The one or more memory devices 104 may include volatile memory technologies, such as dynamic random access memory, synchronous dynamic random access memory, or static random access memory. In some configurations, the one or more memory devices 104 include low-power double data rate memory devices coupled to the memory controller of the processor 102 over one or more memory channels, with each memory channel including a set of data lines, a write clock line, a command and address bus, one or more chip select lines, and a read data strobe line.

As examples, the memory devices 104 can be or can include random access memory (RAM), static RAM (SRAM), dynamic RAM (DRAM), synchronous DRAM (SDRAM), magnetoresistive RAM (MRAM), conductive bridge Random Access Memory (CB-RAM), spin transfer torque (STT)-MRAM, phase change RAM (PRAM), core memory, dual inline memory modules (DIMMs), microDIMMs, MiniDIMMs, block addressable memory device(s) (e.g., those based on NAND or NOR technologies (e.g., single-level cell (SLC), multi-level cell (MLC), quad-level cell (QLC), tri-level cell (TLC), or some other NAND), read-only memory (ROM), programmable ROM (PROM), erasable PROM (EPROM), electrically EPROM (EEPROM), flash memory, non-volatile RAM (NVRAM), solid-state storage, magnetic disk storage mediums, optical storage mediums, memory devices that use chalcogenide glass, multi-threshold level NAND flash memory, NOR flash memory, single or multi-level phase change memory (PCM) and/or phase change memory with a switch (PCMS), NVM devices that use chalcogenide phase change material (e.g., chalcogenide glass), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge random access memory (CB-RAM), or spin transfer torque (STT)-MRAM, a spintronic magnetic junction memory based device, a magnetic tunneling junction (MTJ) based device, a domain wall (DW) and spin orbit transfer (SOT) based device, a thyristor based memory device, and/or a combination of any of the aforementioned memory devices, and/or other memory. Each memory device 104 may be packaged individually or in a vertically stacked arrangement within a common package, and may include one or more independently addressable ranks accessible via respective chip select signals.

The processors 102 and the one or more memory devices 104 communicate via a bus or an interconnect system. The bus represented in FIG. 1 generally illustrates the data pathways within the computing system 100. In practice, this bus may include a complex web of point-to-point interconnects, such as the ultra path interconnect or the quickpath interconnect. These interconnects facilitate high-speed data transfer between different processor sockets and between processors and memory controllers. The memory interface between the memory controller and each memory device 104 may carry multiple physical signal groups: unidirectional command and address signals on the command and address bus (CA), chip select signals (CS), a differential system clock (CK_P/CK_N), a differential write clock (WCK_P/WCK_N) forwarded from the memory controller to the memory devices 104 as a timing reference for data transfers, bidirectional data signals (DQ) that carry read and write data between the memory controller and the memory devices 104, and a differential read data strobe (RDQS_P/RDQS_N) output by a memory device 104 during read operations to provide a timing reference for data sampling at the memory controller. A physical interface (PHY) within the memory controller implements the electrical interface to the memory channel, translating between the digital signals of the memory controller's logic and the analog signals of the memory channel, and incorporates timing calibration circuits that align the sampling points of the memory controller's receive circuitry to the data eye of incoming read data.

The communication resources 130 enable the computing system 100 to exchange data with external entities. The communication resources 130 may include one or more network interface controllers, host bus adapters, or input/output fabric interfaces. The network interface controllers may support various communication standards, such as Ethernet, InfiniBand, or Fibre Channel. The communication resources 130 manage the physical and data link layers of the communication protocols, handling the transmission and reception of data packets. The communication resources 130 connect the computing system 100 to a network 190. The network 190 may be a local area network, a wide area network, the internet, or a dedicated storage area network. Through the network 190, the computing system 100 may access remote hardware resources 180 and external storage 150. For example, the communication resources 130 may include wired communication components, cellular communication components, Wi-Fi components, and other communication components

In various aspects described herein, a capacity of the memory subsystem accessible through the memory controller's data interface may be increased by coupling a plurality of memory devices 104 to a single memory channel, so that the plurality of memory devices 104 may collectively serve the memory controller's data interface and their aggregate storage capacity can be accessible through a single channel interface. In such a configuration, two memory devices 104 each having a data width narrower than the data width of the memory controller's data interface may be coupled to respective non-overlapping portions of the data interface, with the data lines of a first memory device coupled to a first portion of the data interface and the data lines of a second memory device coupled to a second, different portion of the data interface, so that the two memory devices 104 together span the full width of the memory controller's data interface. This approach may allow the memory capacity per channel to be doubled relative to a single-device configuration without modifying the memory controller's data interface width, the physical interface pin assignment, or the core architecture of the memory subsystem. The write clock line, command and address bus, chip select lines, and system clock line of the memory channel are shared between the two memory devices 104, and the read data strobe output of one of the two memory devices 104 is used by the memory controller as the timing reference for sampling data received from both memory devices 104.

A MemSS of the computing system 100 includes the memory controller, the PHY, and associated logic circuits that collectively implement the complete memory interface. A single MemSS design may be instantiated across multiple product variants, referred to as SKUs, that differ in memory capacity or configuration, ranging from configurations employing a single memory device per channel to configurations employing two memory devices per channel in the dual-device arrangement described herein. The ability of a single MemSS to serve multiple product SKUs without a ground-up redesign of the physical interface layer reduces development cost, verification effort, and time to market across the product family, and enables a common physical interface specification to be maintained across all capacity variants

The input/output devices 140 associated with the computing system 100 represent local peripheral interfaces and devices. These may include storage controllers, such as redundant array of independent disks controllers, universal serial bus controllers, and interfaces for human interaction devices like keyboards and monitors if the system is configured for direct user interaction. The input/output devices 140 may also include hardware accelerators, such as field-programmable gate arrays or application-specific integrated circuits, installed to offload specific processing tasks from the processors 102. The bus facilitates the communication between the processors 102 and the input/output devices 140, often utilizing standards like peripheral component interconnect express. FIG. 1 also illustrates input/output devices 140 external to the computing system 100, which may represent peripherals connected via the communication resources 130 or the network 190, providing flexibility in system configuration.

The external storage 150 represents persistent data storage repositories located outside the immediate physical chassis of the computing system 100. The external storage 150 may include storage area networks, network-attached storage systems, or cloud-based storage services. The external storage 150 may store application data and operating system files that are loaded into the one or more memory devices 104 during operation. The connection to the external storage 150 allows for centralized data management and facilitates features such as high availability, where a workload can be restarted on different hardware resources if the primary hardware fails. Access to the external storage 150 is mediated by the communication resources 130 and the protocols of the network 190, such as internet small computer systems interface or non-volatile memory express over fabrics.

The remote hardware resources 180 generally represent other computing nodes or clusters available via the network 190. In a distributed computing system 100, the computing system 100 may function as one physical node in a larger cluster, with the remote hardware resources 180 constituting the other physical nodes. The remote hardware resources 180 may possess similar or different configurations compared to the computing system 100. The ability to communicate with the remote hardware resources 180 enables distributed processing, where a single large task is decomposed into smaller sub-tasks executed in parallel across multiple machines.

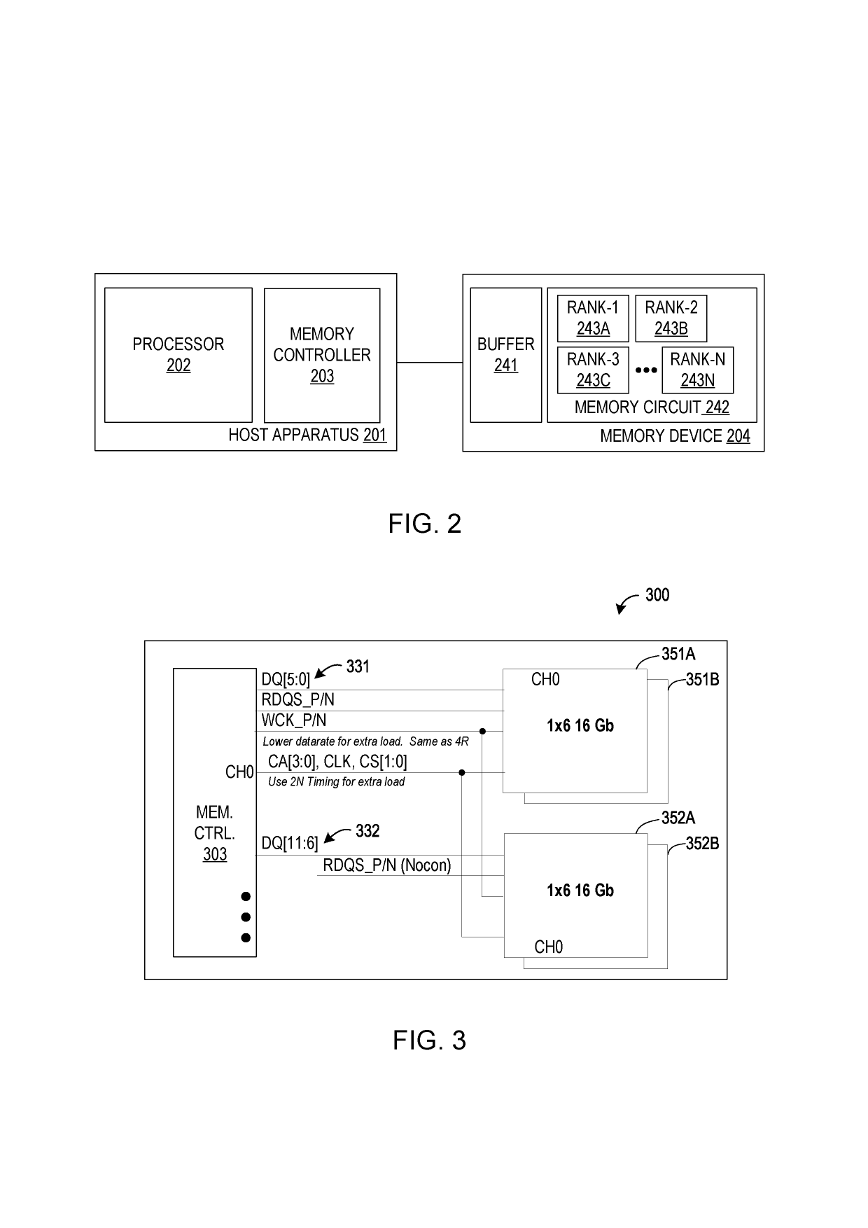

FIG. 2 illustrates a block diagram of an example host apparatus 201 and a memory device 204 in accordance with various aspects described herein. The host apparatus 201 includes a processor 202 and a memory controller 203. The processor 202 and the memory controller 203 may correspond to the processing and memory management components of the computing system. The memory device 204 is coupled to the host apparatus 201. A computing system (the computing system 100) may include the host apparatus 201 as part of a processor (e.g., one of the processors 102) and coupled to the memory device 204 (e.g., one of the memory devices 204).

The memory device 204 may include a buffer 241 and a memory circuit 242, wherein the memory circuit 242 includes a plurality of ranks 243A, 243B, 243C, through 243N that collectively provide the addressable storage capacity of the memory device 204. The host apparatus 201 may communicate with the memory device 204 over a memory channel that carries the full complement of signal groups required for memory operation, including data lines, clock lines, a command and address bus, chip select lines, and read data strobe lines. FIG. 2 illustrates an example of generalized architecture applicable to a range of memory system configurations, and the apparatus according to various aspects described herein.

The processor 202 of the host apparatus 201 may represent the computational element that initiates memory transactions directed to the memory device 204. The processor 202 may generate read and write requests that are forwarded to the memory controller 203. The memory controller 203 may translate those requests into the command sequences, address encodings, and data transfers required by the memory interface specification. The processor 202 may integrate one or more processing cores, a cache hierarchy including multiple levels of cache memory, and an interface to the memory controller 203 through which memory transactions are issued and completed.

The processor 202 and the memory controller 203 may be integrated within a common semiconductor die or package, as illustrated in FIG. 2 by the enclosure of the processor 202 and the memory controller 203 within the host apparatus 201. In certain implementations, the memory controller 203 is integrated directly into the processor die, eliminating the latency and bandwidth constraints that would otherwise arise from a discrete external memory controller.

The memory controller 203 may manage the set of operations required to transfer data between the processor 202 and the memory device 204. The memory controller 203 includes a data interface having a defined data width corresponding to the number of data lines through which the memory controller 203 transfers data to and from the memory device 204. The memory controller 203 may include a combination of: a command and address generation logic configured to assemble and transmit command packets on the command and address bus, a rank selection logic configured to activate the appropriate chip select signals to address specific ranks within the memory device 204, refresh management circuitry configured to issue periodic refresh commands to maintain data integrity in the memory circuit 242, and power management logic configured to control the operating state of the memory device 204.

The memory controller 203 may further include a physical interface layer, referred to as the PHY, that implements the electrical interface between the memory controller's digital logic and the analog signals of the memory channel. The PHY may incorporate transmit drivers, receive samplers, delay-locked loops, and calibration circuits that collectively ensure reliable signal transmission and reception across the memory channel under varying operating conditions.

The memory controller 203 may include a read direction datapath through which data received from the memory device 204 during read operations is captured, aligned, and forwarded to the processor 202. A read data strobe input of the memory controller 203 receives a read data strobe signal output by the memory device 204 during read operations, and the read direction datapath uses the received strobe signal to determine the correct sampling instants for incoming data on the data lines. The read direction datapath may include circuitry for adjusting the sampling point relative to the received strobe signal, including a mechanism for selecting the polarity of the strobe edge, such as rising or falling, used to trigger data sampling. The read direction data path may be configured to apply a phase delay that shifts the sampling point by a programmable amount relative to the selected strobe edge.

The memory controller 203 may further include a finite state machine that measures the unmatched path delay of the read data strobe signal through the PHY receive circuitry, determines the number of unit intervals by which the strobe signal is delayed relative to the data clock, and configures the read direction datapath accordingly so that data is sampled at the center of the data eye. These adjustment mechanisms can provide the memory controller 203 with the ability to accommodate variations in the round-trip timing of the read data strobe signal arising from differences in channel length, PHY calibration state, and memory device characteristics.

The memory controller 203 may include clock generation and distribution circuitry that produces and forwards a write clock signal to the memory device 204 over a write clock line. The write clock signal may be a differential signal, designated WCK_P and WCK_N, that operates at the data rate frequency of the memory channel and serves as the primary timing reference used by the memory device 204 for data output during read operations and for data input sampling during write operations. The clock generation circuitry within the memory controller 203 produces the write clock signal with controlled phase and frequency characteristics that satisfy the timing requirements of the memory interface specification.

The write clock line may route the write clock signal from the write clock output of the memory controller 203 to the clock input of the memory device 204. The signal integrity of the write clock line may be a significant determinant of the maximum achievable data rate of the memory channel. When a write clock line is required to drive the clock inputs of more than one memory device, the capacitive loading on the write clock line may be increased relative to a single-device configuration, and this increased loading affects the rise and fall times of the write clock signal and may reduce the eye height and eye width of the write clock waveform at the device clock inputs. The memory controller 203 may also generate and forward a differential system clock signal, designated CK_P and CK_N, that operates at half the write clock frequency. This differential system clock signal serves as the timing reference for command and address transfers on the command and address bus.

The buffer 241 of the memory device 204 may be interposed between the memory channel and the memory circuit 242. The buffer 241 may be configured to provide signal buffering, command decoding, and interface adaptation functions. The buffer 241 may receive command and address signals from the memory controller 203 over the command and address bus, decode those signals to determine the operation to be performed and the target rank within the memory circuit 242, and issue the appropriate internal commands to the addressed rank.

During read operations, the buffer 241 receives data from the addressed rank within the memory circuit 242 and drives that data onto the data lines of the memory channel toward the memory controller 203, and simultaneously outputs the read data strobe signal that the memory controller 203 uses as a timing reference for data sampling. During write operations, the buffer 241 receives data from the memory controller 203 on the data lines and forwards that data to the addressed rank within the memory circuit 242 for storage. The buffer 241 may also perform impedance matching and signal conditioning functions that improve signal integrity on both the memory channel side and the internal interface to the memory circuit 242.

The memory circuit 242 may include a plurality of ranks 243A, 243B, 243C, through 243N that collectively provide the addressable storage capacity of the memory device 204. Each rank among the ranks 243A through 243N can include an array of storage cells organized into banks and bank groups, and is independently addressable by the memory controller 203 via a respective chip select signal. The memory circuit 242 implements the storage array, row and column address decode logic, sense amplifiers, and input/output circuits required to perform read and write operations in response to commands received from the buffer 241. Each rank among the ranks 243A through 243N may be capable of independently driving the data lines during a read operation and independently receiving data on the data lines during a write operation, with the timing of these operations governed by the write clock signal received from the memory controller 203 via the buffer 241. The number of ranks N within the memory circuit 242 may vary across different memory device configurations, with common configurations including one, two, or four ranks per memory device.

The ranks 243A through 243N within the memory circuit 242 are independently addressable by the memory controller 203 through respective chip select signals carried on the chip select lines of the memory channel. Each rank among the ranks 243A through 243N responds to commands qualified by its respective chip select signal and remains inactive during commands directed to other ranks, allowing the memory controller 203 to interleave operations across multiple ranks to improve effective memory bandwidth. The chip select signals can be routed from the memory controller 203 to the buffer 241 over the memory channel, and the buffer 241 may decode the chip select signals to direct commands to the appropriate rank within the memory circuit 242.

In configurations where two memory devices are coupled to a single memory channel, the chip select signals of the memory channel serve to address ranks within both memory devices. The rank selection logic of the memory controller 203 may account for the mapping of chip select signal states to ranks distributed across the two memory devices. The rank architecture of the memory circuit 242 illustrated in FIG. 2 may provide a general framework applicable to a range of memory device configurations, including configurations in which two memory devices are paired to serve a single memory controller data interface as described in detail in the following section.

FIG. 3 illustrates a schematic diagram of an example apparatus 300 in accordance with various aspects described herein. The apparatus 300 includes a memory controller 303 and two memory devices. A first memory device may include memory dies 351A and 351B, and a second memory device including memory dies 352A and 352B, which are coupled to the memory controller 303 over a memory channel designated CH0. In this example, each memory device is depicted to include two memory dies but this is not limiting. Each memory device may include any number of memory dies. The memory controller 303 of FIG. 3 may correspond to the memory controller 203 described with reference to FIG. 2, and may be integrated within a host apparatus of the type illustrated in FIG. 1 as part of the computing system 100.

The first memory device including memory dies 351A and 351B, and the second memory device including memory dies 352A and 352B, each may correspond to a memory device of the type described with reference to the memory device 204 of FIG. 2. Each of memory dies may include storage arrays organized into independently addressable ranks. In one specific example, the apparatus 300 may represent a specific configuration in which two memory devices, each having a data width of x6, are coupled to the memory controller 303 whose data interface has a data width of x12, so that the two memory devices may together collectively serve the full width of the memory controller's data interface. The signal connections illustrated in FIG. 3, which include data lines 331 and 332, a read data strobe line RDQS_P/N, a write clock line WCK_P/N, a command and address bus CA[3:0], a system clock CLK, and chip select lines CS[1:0], may define the set of physical connections through which the memory controller 303 and the two memory devices communicate over the memory channel CH0.

It is to be recognized that the above-mentioned data width examples are provided throughout this disclosure as an example configuration in which the memory controller is configured to support N data lines, and total number of data lines of multiple memory devices coupled to the memory controller does not exceed N data lines. In an illustrative example, two memory devices may be configured to operate, each with with N/2 data lines, with the memory controller with N-data lines support.

The memory controller 303 may include a data interface that includes the set of signal lines through which data is transferred between the memory controller 303 and the memory devices coupled to the memory channel CH0. As illustrated in FIG. 3, the data interface of the memory controller 303 has a data width of twelve data lines, collectively spanning DQ[11:0], and the data interface is divided into two portions: a first portion including data lines DQ[5:0], designated by reference numeral 331, and a second portion including data lines DQ[11:6], designated by reference numeral 332. The data interface width of the memory controller 303 can designate the number of data bits transferred in parallel during each data transfer operation.

In the apparatus 300, the full twelve-bit width of the data interface may be served by the two memory devices collectively, such that the first memory device including memory dies 351A and 351B drives and receives data on the first portion 331 including DQ[5:0], while the second memory device including memory dies 352A and 352B drives and receives data on the second portion 332 including DQ[11:6]. The data interface of the memory controller 303 may be implemented within the PHY of the memory controller 303 as a set of bidirectional data transceivers, each including a transmit driver and a receive sampler coupled to a respective data line, with all twelve transceivers sharing a common set of timing and calibration circuits that govern the data transfer timing across the full interface width. The data interface of the memory controller 303 may be the same data interface that would be used in a single x12 memory device configuration, which may require no modification to the physical pin assignment or transceiver architecture to accommodate the dual x6 device arrangement of the apparatus 300.

The memory controller 303 further includes a read data strobe input through which the memory controller 303 receives a read data strobe signal from a memory device during read operations. The read data strobe input may be implemented within the PHY of the memory controller 303 as a differential receiver coupled to the RDQS_P and RDQS_N signal lines of the memory channel CH0, and the output of the differential receiver may be routed to the read direction datapath of the memory controller 303 as described with reference to FIG. 2.

The read data strobe input of the memory controller 303 may be a single input. The memory controller 303 may include one read data strobe input associated with the data interface of memory channel CH0, corresponding to the single differential receiver coupled to the RDQS_P/N lines of the channel. This single strobe input may be capable of receiving the read data strobe signal from at most one memory device at a time, and the read direction datapath of the memory controller 303 can use the signal received at this single strobe input as the timing reference for sampling data received on all twelve data lines DQ[11:0] of the data interface.

Correspondingly, the read data strobe input of the memory controller 303 does not require modification from a baseline x12 single-device configuration to implement the apparatus 300, since the strobe input remains a single differential input in both the single-device and dual-device configurations. In this configuration, the distinction between the two configurations may lie in which memory device's strobe output is connected to the strobe input and how the read direction datapath processes the received strobe signal to accommodate data arriving from two devices.

The first memory device including memory dies 351A and 351B may have data lines coupled to the first portion 331 of the data interface of the memory controller 303, specifically the data lines DQ[5:0]. The second memory device including memory dies 352A and 352B may have data lines coupled to the second portion 332 of the data interface of the memory controller 303, specifically the data lines DQ[11:6]. Each of the two memory devices may have a data interface with a data width of x6. In other words, each memory device may include six data output and data input circuits connected to six respective data lines of the memory channel CH0.

During a read operation directed to the first memory device, the memory dies 351A and 351B may drive read data onto the data lines DQ[5:0] of portion 331, while the data lines DQ[11:6] of portion 332 remain driven by the second memory device including memory dies 352A and 352B. During a read operation directed to the second memory device, the memory dies 352A and 352B may drive read data onto the data lines DQ[11:6] of portion 332, while the data lines DQ[5:0] of portion 331 remain driven by the first memory device including memory dies 351A and 351B. In each case, the memory controller 303 may sample data arriving on all twelve data lines DQ[11:0] as a unified data transfer across the full width of the data interface. The coupling of the first memory device's data lines to the first portion 331 and the second memory device's data lines to the second portion 332 may be realized at the package, substrate, or printed circuit board level by routing DQ[5:0] traces from the memory controller 303's PHY to the data pins of the first memory device, and DQ[11:6] traces from the memory controller 303's PHY to the data pins of the second memory device, with no overlap or sharing of individual data lines between the two devices.

A read data strobe line may couple the read data strobe output of the first memory device including memory dies 351A and 351B to the read data strobe input of the memory controller 303. The RDQS_P/N signal line may be routed from the read data strobe output of the first memory device to the read data strobe input of the memory controller 303 as a connected signal path carrying the differential strobe signal. The read data strobe output of the first memory device is the output terminal through which the first memory device can drive the differential RDQS_P and RDQS_N signals during read operations, producing strobe transitions that are edge-aligned with the data outputs DQ[5:0] of the first memory device in accordance with the memory device specification.

The read data strobe line may be a differential transmission line pair routed on the package substrate or printed circuit board, extending from the RDQS_P and RDQS_N output pins of the first memory device to the RDQS_P and RDQS_N input pins of the memory controller 303's PHY. The read data strobe line may be implemented as a microstrip or stripline differential pair with controlled characteristic impedance, configured to carry the high-frequency differential strobe signal with minimal reflection, attenuation, and skew between the positive and negative conductors. The RDQS_P/N connection illustrated in FIG. 3 from the first memory device to the memory controller 303 may be the sole read data strobe connection in the apparatus 300. In other words, only one of the two memory devices may have its read data strobe output connected to the memory controller 303, and this single connection constitutes the complete read data strobe interface between the memory controller 303 and the memory channel CH0 for the purpose of data sampling.

The memory controller 303 may be configured to sample data received from both the first memory device including memory dies 351A and 351B and the second memory device including memory dies 352A and 352B based on the read data strobe signal received at the read data strobe input.

During a read operation directed to the first memory device, the memory controller 303 receives the RDQS_P/N signal from the first memory device at the read data strobe input and uses the transitions of that signal to trigger the sampling of data arriving on data lines DQ[5:0] of the first portion 331. The RDQS_P/N signal from the first memory device may be edge-aligned with the first memory device's DQ[5:0] output, and the memory controller 303's read direction datapath applies an internal phase delay to the received strobe signal to center the sampling point within the data eye of the DQ[5:0] data. During a read operation directed to the second memory device, the memory controller 303 again receives the RDQS_P/N signal at its read data strobe input. However, in this case, the RDQS_P/N signal continues to originate from the first memory device (rather than the second memory device), because only the first memory device's strobe output is connected to the controller. The memory controller 303 uses this same RDQS_P/N signal from the first memory device as the timing reference for sampling data arriving on data lines DQ[11:6] of the second portion 332 from the second memory device.

The second memory device may drive data on DQ[11:6] in temporal relation to the same write clock signal WCK_P/N that the first memory device uses to produce its data and strobe outputs, so the RDQS_P/N signal of the first memory device can provide a valid, usable timing reference for the second memory device's data. Illustratively, this may be subject to any difference in the internal signal propagation delays of the two devices, which may be facilitated by timing compensation circuitry as described herein. The memory controller 303 may implement the sampling of data from both memory devices within a common read direction datapath, with the strobe signal from the first memory device being applied as the sampling reference for all twelve data lines DQ[11:0], or may implement separate per-device-group sampling logic for DQ[5:0] and DQ[11:6] with respective timing adjustments applied to each group independently.

The configuration of the memory controller 303 to sample data from both memory devices based on the single read data strobe signal received at the read data strobe input may be implemented through the read direction datapath described with reference to FIG. 2. Specifically, the read direction datapath of the memory controller 303 may route the output of the differential receiver coupled to the RDQS_P/N signal line to the sampling control logic for all twelve data lines DQ[11:0] of the data interface, rather than routing separate per-device strobe signals to separate groups of data line samplers. The sampling control logic may generate sample clock signals derived from the received RDQS_P/N transitions and apply those sample clock signals to the data samplers of both the first portion 331 including DQ[5:0] and the second portion 332 including DQ[11:6].

The memory controller 303 may be configured at initialization time, for example, through programming of configuration registers within the PHY, to activate this shared-strobe sampling mode in which the RDQS_P/N signal received from the first memory device is used as the timing reference for both device groups. In this way, the configuration of the memory controller 303 to sample data from both memory devices based on the single strobe signal may be an operational characteristic of the read direction datapath that is established during system initialization and maintained throughout normal operation.

In an example, each of the first and second memory devices is configured to output read data on its respective data lines in temporal relation to a clock signal received from the memory controller 303. As illustrated in FIG. 3, the write clock signal WCK_P/N is distributed from the memory controller 303 to both the first memory device including memory dies 351A and 351B and the second memory device including memory dies 352A and 352B over a shared write clock line. Each memory device receives the WCK_P/N signal at its clock input and uses edges of the write clock signal as timing references for its internal read datapath. Specifically, when the first memory device receives a read command, the internal datapath of the first memory device transfers data from the storage array to the output drivers, and the output drivers place data transitions on DQ[5:0] at a time determined by the tWCK2DQO delay of the first memory device after a write clock edge. Similarly, when the second memory device receives a read command, the internal datapath of the second memory device places data transitions on DQ[11:6] at a time determined by the tWCK2DQO delay of the second memory device after a write clock edge.

Because both memory devices derive their data output timing from the same WCK_P/N signal received from the memory controller 303, the data outputs of the two devices are in temporal relation to a common clock reference. The memory controller 303 may simultaneously or in sequence issue read commands to the first and second memory devices, and in each case the responding memory device may output data on its respective data lines in temporal relation to the received write clock signal, allowing the memory controller 303 to anticipate the approximate timing of incoming data based on its knowledge of the write clock frequency and the expected tWCK2DQO delay range. The tWCK2DQO delay of each memory device may fall within a range of 600 to 1600 picoseconds across the device population, meaning that data appears on the data lines between 600 and 1600 picoseconds after the triggering write clock edge at the device clock input, with the exact delay determined by the process, voltage, and temperature conditions of the individual device.

In an example, the memory controller 303 is configured to be unresponsive to a read data strobe output of the other of the first and second memory devices. As illustrated in FIG. 3, the RDQS_P/N output of the second memory device including memory dies 352A and 352B is designated as a no-connect (Nocon). In an example, this corresponds to that the second memory device's strobe output is not routed to the memory controller 303. The memory controller 303 may be configured to be unresponsive to the second memory device's strobe output in the sense that the controller's read direction datapath does not process, route, or act upon any signal that the second memory device drives on its RDQS_P/N output terminals.

This unresponsiveness may be achieved through physical disconnection, or alternatively through logical gating within the PHY in which the receiver associated with the second strobe input is disabled, or its output is masked from the sampling control logic, or the routing from the receiver output to the read direction datapath is severed through programmable multiplexer configuration. In an implementation where the memory controller 303's PHY is designed to support both single-device and dual-device configurations, the unresponsiveness to the second device's strobe may be established during initialization by configuring the PHY to disable the receive path associated with the second strobe input when operating in the dual-device mode. In another implementation, the PHY may be configured exclusively for the dual-device configuration and may physically omit the receive circuitry for the second strobe path entirely, so that the unresponsiveness is structural rather than programmable. In any of these implementations, the result is that the memory controller 303's sampling behavior is governed exclusively by the strobe signal received from the first memory device, regardless of the state of the second memory device's RDQS_P/N output terminals.

In a further example, the read data strobe output of the other of the first and second memory devices is electrically disconnected from the read data strobe input of the memory controller 303. As illustrated in FIG. 3, the RDQS_P/N signal from the second memory device including memory dies 352A and 352B is marked as a no-connect. In an example, it corresponds to that the RDQS_P and RDQS_N output pins of the second memory device are not connected by any signal trace to the RDQS_P and RDQS_N input pins of the memory controller 303. This electrical disconnection may be implemented at the physical design level, such that no trace is routed from the RDQS_P/N output pads of the second memory device to the memory controller 303's PHY strobe receiver on the package substrate or printed circuit board. The RDQS_P/N output pads of the second memory device may be left as no-connect pads in the package ball-out or board layout, such that the second memory device's strobe output terminals are electrically floating or terminated locally without any connection to the memory controller 303. Alternatively, in a package-level implementation, the bond wires or redistribution layer traces that would conventionally connect the second memory device's RDQS_P/N die pads to the package substrate and onward to the memory controller 303 are omitted from the package design.

The electrical disconnection ensures that no signal path exists through which the second memory device's strobe output can influence the voltage on the RDQS_P/N signal lines of the memory channel CH0, and therefore that the RDQS_P/N signal lines carry only the strobe signal from the first memory device. This improves the signal integrity. Illustratively, if the second memory device's RDQS_P/N output were connected but ignored by the memory controller 303, the second device's output driver would contend with the first device's output driver on the shared RDQS_P/N line during read operations, creating signal integrity problems that would compromise the strobe quality received by the memory controller 303.

In an example, the memory controller 303 further includes timing compensation circuitry. The timing compensation circuitry is configured to compensate for a difference in signal propagation delay between the first memory device including memory dies 351A and 351B and the second memory device including memory dies 352A and 352B.

When the two memory devices share a single RDQS_P/N connection as described above, the memory controller 303 may use the strobe signal from the first memory device as the timing reference for sampling data from both devices. The strobe transitions generated by the first memory device may be edge-aligned with the first memory device's DQ[5:0] output. In other words, the strobe accurately represents the timing of data arriving from the first memory device. However, the second memory device has its own tWCK2DQO delay that may differ from the tWCK2DQO delay of the first memory device. If the second memory device's tWCK2DQO delay is greater than that of the first memory device, then data on DQ[11:6] arrives at the memory controller 303 later than data on DQ[5:0] relative to the received RDQS_P/N transitions. In other words, if the memory controller 303 samples DQ[11:6] at the same time as DQ[5:0], the sampling point for DQ[11:6] will be too early and may fall outside the valid data window. Conversely, if the second memory device's tWCK2DQO delay is smaller, the sampling point will be too late for DQ[11:6].

The timing compensation circuitry within the memory controller 303 can address this delay difference. The timing compensation circuitry may be configured to determine the magnitude and direction of the inter-device delay difference and apply a corrective timing adjustment to the sampling of data from the second memory device relative to the shared RDQS_P/N signal. The timing compensation circuitry may be part of the read direction datapath of the memory controller 303. The timing compensation circuitry may include configurable delay elements, per-device-group phase interpolators, or programmable FIFO read pointer offsets that are configured to shift the effective sampling instant for DQ[11:6] earlier or later relative to the RDQS_P/N-derived sample clock. The low-frequency component of the inter-device delay difference may be based on the fixed tWCK2DQO difference between the two devices at a given process, voltage, and temperature condition. Higher-frequency, dynamic variations in the inter-device delay difference, such as those arising from fast temperature or voltage transients, can be addressed through device pairing techniques as described herein.

In an example, the timing compensation circuitry may be configured to apply a respective sampling timing offset for data received from each of the first and second memory devices relative to the read data strobe signal. For example, the timing compensation circuitry may apply a first sampling timing offset to the sampling of data received from the first memory device on data lines DQ[5:0] of the first portion 331. The timing compensation circuitry may further apply a second, distinct sampling timing offset to the sampling of data received from the second memory device on data lines DQ[11:6] of the second portion 332. In some examples, both offsets are expressed relative to the RDQS_P/N signal received at the read data strobe input of the memory controller 303, which is the common timing reference for both groups of data lines.

The first sampling timing offset may be determined by the round-trip delay of the read path associated with the first memory device, including the RDQS_P/N propagation delay from the first memory device to the memory controller 303 through the read data strobe line. For example, the finite state machine within the memory controller 303, as described with reference to FIG. 2, may measure the unmatched RDQS path delay and round up to the nearest integer number of unit intervals, establishing a baseline offset for the first memory device group. The second sampling timing offset may be determined by the same baseline measurement plus an additional per-device offset X that accounts for the tWCK2DQO difference between the second memory device and the first memory device. In an example, the additional offset X may be determined during a training procedure as described herein. The additional offset X may be positive or negative, advancing or retarding the sampling point for DQ[11:6] relative to the sampling point for DQ[5:0] to compensate for the inter-device delay difference. In this way, the timing compensation circuitry can independently optimize the sampling instant for each of the two device groups while using a single shared RDQS_P/N signal as the common timing reference for both groups.

In an example, the respective sampling timing offset may be bounded by a predetermined maximum number of unit intervals of a data clock signal. The timing compensation circuitry of the memory controller 303 may be configured to accommodate a maximum inter-device tWCK2DQO mismatch of +2 unit intervals or -2 unit intervals of the data clock signal. Illustratively, this corresponds to a physical time difference of plus or minus 200 picoseconds at a data rate of 10 gigatransfers per second. This bound of plus or minus two unit intervals may define the maximum offset that the timing compensation circuitry can apply to the sampling of data from the second memory device relative to the first memory device's RDQS_P/N signal.

The bound may be established by the range of the preamble edge selection mechanism within the read direction datapath. Correspondingly, the memory controller 303 may select a preamble RDQS edge that is one unit interval earlier or one unit interval later than the nominal preamble edge position, to provide a total compensable range of two unit intervals in either direction. A mismatch within this range can be fully compensated by selecting the appropriate preamble edge and applying the corresponding phase delay.

In some examples, the inter-device tWCK2DQO mismatch can exceed plus or minus two unit intervals. Correspondingly, the apparatus 300 may further rely on device pairing techniques to ensure that the actual mismatch between paired devices remains within the compensable range. The JEDEC memory device specification can define a tWCK2DQO range of 600 to 1600 picoseconds across the device population, which may correspond to a maximum population-wide mismatch of up to approximately ten unit intervals at 10 gigatransfers per second.

In an example, the timing compensation circuitry is configured to select, for each of the first and second memory devices, a respective sampling edge polarity and a respective phase delay for sampling data received from that memory device. The selection of sampling edge polarity may refer to the choice of whether the memory controller 303 uses the rising edge or the falling edge of the RDQS_P/N signal to trigger the sampling of data from a given memory device.

The RDQS_P/N signal is a differential strobe that toggles at the data rate, presenting both rising and falling edges in alternation. The preamble of the RDQS_P/N signal, which the preamble is the portion of the strobe that precedes the first valid data edge, determines which edge the memory controller 303 uses as the first sampling trigger for a given read burst. By selecting an earlier preamble RDQS edge (one unit interval before the nominal preamble) for the second memory device relative to the first, or a later preamble RDQS edge (one unit interval after the nominal preamble), the timing compensation circuitry can effectively shift the sampling window for DQ[11:6] by one unit interval relative to DQ[5:0].

In an example, the read direction datapath may configure the write-sample polarity register for the second device group, e.g., by determining whether data on DQ[11:6] is sampled on the rising or falling write clock edge, independently of the write-sample polarity configured for the first device group to implement edge polarity selection. The selection of phase delay may include the adjustment of a fractional unit interval offset applied to the sampling point within the selected unit interval, realized by configuring the FIFO read reset value for the second device group independently of the FIFO read reset value for the first device group. Together, the edge polarity selection and the phase delay selection can provide two independent degrees of freedom for positioning the sampling point for each device group. For example, the edge polarity selection provides coarse, integer-unit-interval adjustments, while the phase delay selection provides fine, sub-unit-interval adjustments within the selected unit interval. The two degrees of freedom may be configured identically for the two device groups, in which case the sampling points for DQ[5:0] and DQ[11:6] are aligned, or may be configured differently, in which case the sampling point for DQ[11:6] is shifted relative to the sampling point for DQ[5:0] by a combination of an integer unit interval offset and a fractional phase delay, together constituting the total timing offset X applied to compensate for the inter-device tWCK2DQO difference.

In an example, the timing offset is determined by a training procedure executed during initialization of the apparatus 300. The training procedure may include a sweep across a plurality of candidate timing offset values and selection of a timing offset value based on data validity detected during the sweep. In an example, a processor (e.g., the processor 202 of the host apparatus 201) may execute a firmware to implement the training procedure during the memory initialization sequence performed at system boot time, such as before the memory subsystem is made available for normal operation.

For example, the training procedure may cause the memory controller 303 to issue a series of read commands to the second memory device including memory dies 352A and 352B, with each read command followed by a comparison of the data received on DQ[11:6] against a known pattern previously written to the second memory device. For each comparison, the timing compensation circuitry of the memory controller 303 may be configured with a different candidate timing offset value for the second device group, and the data validity is recorded for each candidate offset value. The memory controller 303 may determine the data validity by determining whether the received data matches the expected pattern. The candidate offset values can span a range of four unit intervals centered on the nominal offset, providing coverage of the full plus or minus two unit interval compensation range. After the sweep is complete, the firmware may analyze the data validity results to identify the range of offset values for which valid data was detected. The firmware may further select a timing offset value near the center of the valid range to maximize the timing margin for subsequent normal operation.

The selected timing offset value is then programmed, e.g., by the processor, into the timing compensation circuitry of the memory controller 303 and retained for use throughout the operating lifetime of the system until the next initialization sequence. The training procedure for the second device group may be performed in addition to the standard RDQS training procedure performed for the first device group, and may reuse much of the same firmware infrastructure and hardware support circuitry, with the primary distinction being that the candidate offset values for the second device group span a wider range and the selected offset may differ from the offset selected for the first device group by up to plus or minus two unit intervals.

In an example, the apparatus 300 further includes a write clock line coupling a write clock output of the memory controller 303 to clock inputs of both the first memory device including memory dies 351A and 351B and the second memory device including memory dies 352A and 352B. Each of the first and second memory devices may have a data interface with a data width narrower than a data width of the data interface of the memory controller 303.

As illustrated in FIG. 3, the WCK_P/N signal is routed from the memory controller 303 to both memory devices over the memory channel CH0, with the write clock line branching to reach the clock inputs of both the first and second memory devices. Each of the two memory devices has a data width of x6 in view of the data width of x12 of the memory controller 303's data interface. The write clock line carries the WCK_P/N differential signal at the data rate frequency, providing the timing reference that both memory devices use for data output and data input operations as described above. The write clock line in the apparatus 300 drives two memory device clock inputs in parallel, doubling the capacitive load on the write clock line relative to a single-device configuration in which only one x12 memory device's clock input would be driven.

As annotated in FIG. 3, this doubled loading introduces a constraint on the achievable data rate compared to a single-device configuration, analogous to the data rate constraint encountered in a four-rank configuration where multiple die are driven from a common clock line. The narrower data width context may be relevant because it is specifically the use of two x6 devices to replace a single x12 device that gives rise to the doubled write clock loading in the apparatus 300.

In an example, the write clock line includes a signal trace having a controlled impedance profile and electromagnetic isolation configured to mitigate signal integrity impact of capacitive loading from both the first and second memory devices. The signal trace implementing the write clock line may be arranged with a characteristic impedance that is selected and maintained along the length of the trace to minimize signal reflections. It may preserve the rise time, fall time, eye height, and eye width of the WCK_P/N waveform at the clock inputs of both memory devices. The controlled impedance profile of the signal trace can account for the increased capacitive loading imposed by two memory device clock inputs by adjusting the trace geometry, including trace width, dielectric thickness, and proximity to reference planes, to achieve a characteristic impedance that is appropriate for the loaded line rather than the unloaded line.

Electromagnetic isolation of the write clock line may be implemented through the use of guard traces, via shielding, and controlled routing separation from adjacent signal traces, particularly from the data lines DQ[5:0] and DQ[11:6] and from the command and address bus CA[3:0], to minimize capacitive and inductive crosstalk between the write clock trace and neighboring signal conductors. The electromagnetic isolation may be important because the WCK_P/N signal operates at the full data rate frequency and is therefore a significant source of crosstalk that could degrade the signal integrity of adjacent data and address lines if not properly isolated. Signal integrity simulations of the write clock line with dual-device loading, of the type described in the invention disclosure, have demonstrated that with appropriate impedance engineering and electromagnetic isolation, the WCK_P/N eye diagram at the memory device clock inputs in the apparatus 300 can be maintained at a level comparable to, or better than, the eye diagram achievable with separate per-device write clock lines, while consuming less signal routing area and lower power than a configuration with duplicated write clock connections.

In a further example, the signal trace has an impedance transition at a branch point where the signal trace divides toward the first and second memory devices. As illustrated in FIG. 3, the WCK_P/N write clock line routes from the memory controller 303 to a branch point where the signal trace divides, with one branch routed to the clock input of the first memory device including memory dies 351A and 351B and another branch routed to the clock input of the second memory device including memory dies 352A and 352B. The impedance transition at the branch point may be configured to compensate for this change. For example, the impedance of the signal trace before the branch point may be set to a higher value than the impedance of each branch after the branch point, so that the combined effect of the two parallel branches at the branch point matches the impedance of the trace before the branch, minimizing the reflection coefficient at the branch point discontinuity.

For example, if each branch has a characteristic impedance of fifty ohms after the branch point, the trace before the branch point may be designed with a characteristic impedance of one hundred ohms, so that the parallel combination of the two fifty-ohm branches presents an effective impedance of twenty-five ohms at the branch node. Further, the transition from one hundred ohms to twenty-five ohms at the branch point can be managed through careful geometric tapering or discrete impedance step design to minimize the reflected signal energy. The impedance transition at the branch point may be implemented through control of the trace geometry on the package substrate or printed circuit board at the location of the branch, using design techniques such as trace width tapering, controlled via placement, and dielectric thickness adjustment to achieve the desired impedance profile in the immediate vicinity of the branch point.

In an example, each of the first and second memory devices includes a plurality of ranks independently addressable by the memory controller 303. As illustrated in FIG. 3, the first memory device includes memory dies 351A and 351B, and the second memory device includes memory dies 352A and 352B, with each pair of memory dies may represent the rank structure of the respective memory device. The memory controller 303 addresses the ranks of the first and second memory devices via the chip select lines CS[1:0] carried on the memory channel CH0. The chip select lines CS[1:0] may be shared between the first and second memory devices, with each chip select signal activating a respective rank across both memory devices simultaneously or selectively, depending on the addressing scheme implemented by the memory controller 303.

Each rank of the first memory device including memory dies 351A and 351B may drive data onto the data lines DQ[5:0] of the first portion 331 when addressed by the memory controller 303, and each rank of the second memory device including memory dies 352A and 352B drives data onto the data lines DQ[11:6] of the second portion 332 when addressed. A configuration including two ranks per memory device, such as a dual-rank configuration using memory dies 351A and 351B for the first memory device and memory dies 352A and 352B for the second memory device, allows the memory controller 303 to interleave read and write operations between ranks of the two devices to improve effective memory bandwidth and reduce access latency through rank-level parallelism. The number of ranks per memory device may be one, two, or four in different implementations of the apparatus 300, with the total accessible capacity per channel scaling with the number of ranks and the per-rank storage density of each memory device.

In an example, the data lines of the first memory device are coupled to a first portion of the data interface and the data lines of the second memory device are coupled to a second, different portion of the data interface. As illustrated in FIG. 3, the data lines of the first memory device including memory dies 351A and 351B are coupled to the first portion 331 of the data interface of the memory controller 303, including data lines DQ[5:0], and the data lines of the second memory device including memory dies 352A and 352B are coupled to the second portion 332 of the data interface, including data lines DQ[11:6]. The first portion 331 and the second portion 332 are non-overlapping subsets of the full twelve-bit data interface DQ[11:0] of the memory controller 303, with the first portion including the lower six bits DQ[5:0] and the second portion including the upper six bits DQ[11:6].

During any given read or write operation, each memory device drives or receives data exclusively on its own designated portion of the data interface and has no electrical connection to the other portion. The partitioning of the data interface into the first portion 331 and the second portion 332 is a fixed, static assignment that is established by the physical routing of the DQ[5:0] traces to the first memory device and the DQ[11:6] traces to the second memory device, and is not changed or reconfigured during normal operation. The memory controller 303's read direction datapath treats data received on DQ[5:0] and data received on DQ[11:6] as belonging to the first and second memory devices respectively, applying the respective sampling timing offsets for each portion as described above, so that the data from both portions is captured with appropriate timing compensation despite being sampled from a common RDQS_P/N reference.

In a further example, a data width of each of the first and second memory devices is half of a data width of the data interface of the memory controller 303. As described above and illustrated in FIG. 3, each of the first memory device including memory dies 351A and 351B and the second memory device including memory dies 352A and 352B has a data width of x6, while the data interface of the memory controller 303 has a data width of x12.

In an example, the shared command and address bus CA[3:0], system clock CLK, and chip select lines CS[1:0] illustrated in FIG. 3 are operated using two-cycle (2N) command timing in which one command is transmitted every two system clock cycles rather than every system clock cycle. The apparatus 300 may also adapt the burst length and data packet formatting to account for the narrower data width of the x6 memory devices relative to the x12 controller interface. Specifically, the burst length may be adjusted so that the total number of bits transferred per data packet across the full x12 data interface is maintained, with each x6 device contributing half the bits of each packet over a correspondingly longer burst. The address decoder of the memory controller 303 may be modified to map addresses appropriately across the first and second memory devices, accounting for the division of the data interface between the two devices and ensuring that read and write operations directed to any address within the memory capacity of the apparatus 300 are correctly dispatched to the appropriate device and rank. These logical modifications, including the 2N CA timing adaptation, burst length adjustment, address decoder modification, and per-device sampling offset logic, may represent a scope of change approximately ten times smaller than would be required to redesign the PHY or memory controller architecture to natively add additional strobe or clock connections per channel, enabling a single memory subsystem design to serve the full product family ranging from single x12 device configurations to the dual x6 device configuration of the apparatus 300.

In an example, the apparatus 300 is configured to provide 256 GB of aggregate accessible memory capacity across a sixteen-channel system. In this example, each of the first memory device and the second memory device is a 1x6 16 Gb device arranged in a dual-rank configuration, with a first rank die 351A and a second rank die 351B constituting the first memory device, and a first rank die 352A and a second rank die 352B constituting the second memory device. The total accessible capacity of the apparatus 300 in this example is calculated as 32 Gb per die × 2 ranks per device × 2 devices per channel × 16 channels = 256 GB.

In this example, each x6 memory die of the apparatus 300 is organized with an 8×4 bank group by bank architecture, including eight bank groups each containing four banks. Each x6 die employs a column architecture with twice the column depth of a comparably-sized x12 memory device, so that the reduced number of parallel data lines relative to an x12 device is compensated by a deeper column address space, allowing each x6 die to achieve 16 Gb of storage density without modification to the die area or storage array architecture. Each of the two memory devices contributes 4 GB of accessible capacity per channel in this example, with the first memory device driving data lines DQ[5:0] of the first portion 331 and the second memory device driving data lines DQ[11:6] of the second portion 332, collectively serving the full x12 data interface of the memory controller 303.

In this example, the apparatus 300 achieves the 256 GB capacity target while preserving the physical interface pin assignment of a baseline single x12 device configuration, through the strobe-sharing and write clock sharing arrangements described with reference to FIG. 3. The primary performance trade-off in this example is a modest reduction in achievable data rate relative to a conventional per-device strobe and clock configuration, arising from the doubled capacitive loading on the shared write clock line WCK_P/N. As described with reference to FIG. 3 and FIG. 6, this degradation can be substantially reduced through impedance engineering of the write clock trace and through device pairing techniques that minimize the tWCK2DQO mismatch between the paired rank dies, with data rate parity being achievable in examples where the inter-device mismatch is sufficiently small.

In an example, when the memory controller 303 receives the RDQS_P/N signal from the first memory device at the read data strobe input, the transitions of that signal may be edge-aligned with data arriving on DQ[5:0] from the first memory device, but are offset by a fixed amount relative to data arriving on DQ[11:6] from the second memory device. This fixed offset, which is equal to the difference in tWCK2DQO between the second memory device and the first memory device, constitutes the systematic component of the inter-device delay difference that the timing compensation circuitry is configured to correct.

In an example, the timing compensation circuitry of the memory controller 303 represents the inter-device tWCK2DQO difference as an offset X expressed in unit intervals of the data clock signal, where X may be positive or negative depending on whether the second memory device's tWCK2DQO delay is greater or smaller than that of the first memory device. The offset X is applied by configuring the read direction datapath of the memory controller 303 independently for the first device group including DQ[5:0] and the second device group including DQ[11:6], such that the sampling instant for DQ[11:6] is shifted relative to the sampling instant for DQ[5:0] by the amount X. The finite state machine within the memory controller 303 measures the unmatched RDQS path delay through the PHY receive circuitry and establishes a baseline integer unit interval alignment for the first device group, and the offset X for the second device group is applied as an additional adjustment relative to this baseline, accommodating tWCK2DQO mismatches of up to plus or minus two unit intervals between the two memory devices.

In an example, the selection of sampling edge polarity for each of the first and second memory devices, as described with reference to FIG. 3, corresponds to the selection of whether the read direction datapath begins sampling data from a given device group on a rising or falling edge of the write clock signal derived from the received RDQS_P/N preamble. When the tWCK2DQO of the second memory device differs from that of the first memory device by approximately one unit interval, the timing compensation circuitry selects a preamble RDQS edge that is one unit interval earlier or later than the preamble edge selected for the first device group, effectively shifting the entire sampling window for DQ[11:6] by one unit interval relative to the sampling window for DQ[5:0]. This edge polarity selection is implemented by configuring the write-sample polarity register for the second device group — specifying whether data on DQ[11:6] is captured on the rising or falling write clock edge — independently of the write-sample polarity configured for the first device group. The two device groups may therefore be configured with identical or opposite write-sample polarities depending on the magnitude and direction of the inter-device tWCK2DQO offset X.

In an example, the selection of phase delay for each of the first and second memory devices corresponds to the configuration of the FIFO read reset value for each device group within the read direction datapath of the memory controller 303. The FIFO read reset value determines the fractional unit interval offset applied to the sampling point within the unit interval selected by the edge polarity mechanism, providing a fine adjustment that positions the sampling point at the center of the data eye for each device group independently. The FIFO read reset value for the second device group may differ from the FIFO read reset value for the first device group by an amount corresponding to the sub-unit-interval component of the inter-device tWCK2DQO difference, so that after both the coarse edge polarity adjustment and the fine phase delay adjustment are applied, the sampling point for DQ[11:6] is centered within the valid data window of the second memory device. The edge polarity selection and the FIFO read reset value adjustment together constitute the two independent degrees of freedom described with reference to FIG. 3 — the former providing integer unit interval adjustments and the latter providing sub-unit-interval adjustments — and their combined effect determines the total sampling timing offset applied to each device group relative to the shared RDQS_P/N signal.

In an example, the training procedure described with reference to FIG. 3 determines the offset X and the associated edge polarity and phase delay settings for the second device group by sweeping across candidate offset values spanning four unit intervals and identifying the candidate values for which data received on DQ[11:6] is valid. The sweep width of four unit intervals is chosen to cover the full plus or minus two unit interval compensation range of the timing compensation circuitry, ensuring that the correct offset is identified regardless of the sign or magnitude of the inter-device tWCK2DQO difference within the compensable range. The training procedure selects the offset value nearest the center of the valid range, maximizing the timing margin for DQ[11:6] during subsequent normal operation, and programs the selected edge polarity and phase delay settings into the read direction datapath configuration registers of the memory controller 303. In examples where the two memory devices are closely matched in tWCK2DQO delay through the device pairing techniques described with reference to FIG. 6, the valid range identified by the training sweep is wide, the selected offset X is small, and the timing margin for DQ[11:6] approaches that achievable with a dedicated per-device strobe connection.

In an example, the first memory device and the second memory device of the apparatus 300 may have mutually matched internal signal propagation delays. In this example, the delays may be matched to within a predetermined number of unit intervals of the data clock signal. The timing compensation circuitry of the memory controller 303 may accommodate inter-device tWCK2DQO mismatches of up to plus or minus two unit intervals, establishing the maximum tolerance within which the matched delays must fall for the apparatus 300 to operate correctly across its full data rate range.

When the two memory devices are matched to within this tolerance, the training procedure may identify a valid sampling offset for the second device group, and the timing margin for data received on DQ[11:6] can be sufficient for reliable operation. A tighter matching, for example, within plus or minus one unit interval, can yield a wider valid range during the training sweep and correspondingly greater timing margin. The tolerance expressed in unit intervals may be a frequency-normalized criterion that remains applicable across different data rate specifications, with the physical time corresponding to one unit interval decreasing as the data rate increases. The predetermined maximum tolerance may therefore be a design parameter of the apparatus 300 that is set by the compensation range of the timing compensation circuitry and communicated to the device selection or binning process to ensure that only device pairs meeting the tolerance criterion are used in the apparatus 300.

In an example, the matched internal signal propagation delays include at least one of: i) a delay from a write clock edge to a data output transition at each memory device, which is denoted tWCK2DQO, or ii) a delay from a data strobe input to a data input sampling point at each memory device, which is denoted tWCK2DQI. The tWCK2DQO delay, which may range from 600 to 1600 picoseconds across the device population, may be the more critical parameter for the apparatus 300 because this parameter directly corresponds to the timing of data arriving on DQ[5:0] and DQ[11:6] relative to the shared RDQS_P/N signal. In this constellation, an inter-device tWCK2DQO mismatch that exceeds the compensation range of the timing compensation circuitry causes sampling errors for the second device group.

The tWCK2DQI delay, ranging from 250 to 600 picoseconds, governs the write-side data input sampling point and is a less critical matching parameter due to its narrower population spread. Matching both tWCK2DQO and tWCK2DQI between the two memory devices provides the maximum timing margin for both read and write operations in the apparatus 300. In read-dominated workloads, matching tWCK2DQO alone may be sufficient. The matching criterion may be applied to the absolute delay values at a nominal process, voltage, and temperature condition, or to the delay values measured across a range of operating conditions, with the latter providing greater assurance that the inter-device mismatch remains within the tolerance over the full operating lifetime of the apparatus 300.

In an example, each of the first and second memory devices includes a delay measurement circuit configured to generate a timing signal representative of the respective internal signal propagation delay. Furthermore, the matched delays may be based on respective timing signals generated by the delay measurement circuits of the first and second memory devices. The delay measurement circuit within each memory device may be a purpose-built oscillator, specified in the memory device standard, that measures the tWCK2DQO path delay within a few picoseconds by counting oscillation cycles over a defined measurement window. A corresponding oscillator for measuring the tWCK2DQI delay may also be available within each memory device. The timing signals generated by these oscillators are readable via the memory device's mode register interface, allowing the memory controller 303 or external test equipment to retrieve the measured delay value from each device. The retrieved delay measurements from candidate device pairs may be compared, and pairs whose tWCK2DQO measurements differ by less than the predetermined tolerance threshold, preferably less than one unit interval, can be selected for use together as the first and second memory devices of the apparatus 300.

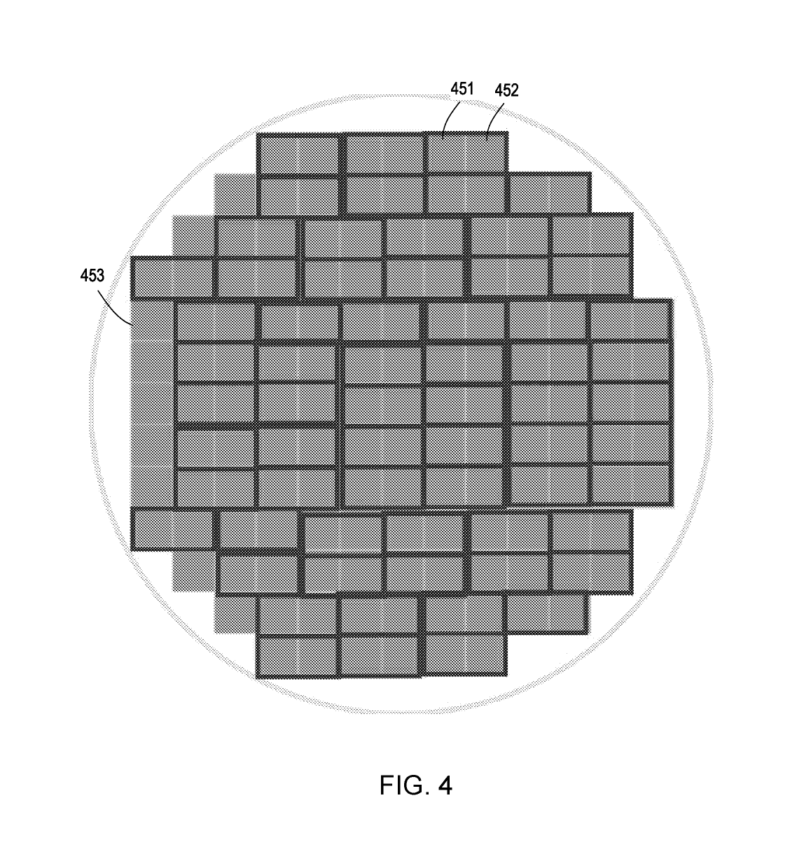

In an example, the first and second memory devices are from adjacent die locations on a common semiconductor wafer. FIG. 4 illustrates a schematic representation of a semiconductor wafer 450 showing the die shot map, with individual die locations arranged in a regular grid across the wafer surface. Reference numerals 451 and 452 identify a pair of adjacent die locations on the wafer 450 whose respective memory dies may be selected for use as the first and second memory devices of the apparatus 300.

The selection of adjacent die locations can exploit the well-established principle that process variation across a semiconductor wafer is spatially correlated, in which dies that are physically proximate on the wafer experience nearly identical implant doses, etch depths, oxide thicknesses, and thermal histories during fabrication, resulting in closely matched transistor characteristics and therefore closely matched internal signal propagation delays. The spatial correlation of process variation means that the tWCK2DQO values of adjacent dies are substantially more similar to each other than the tWCK2DQO values of dies drawn at random from the full wafer population, providing a practical and low-cost pairing strategy that requires no additional measurement infrastructure beyond what is already present in the standard device test flow. Adjacent die locations may be horizontally adjacent, vertically adjacent, or diagonally adjacent on the wafer 450, with horizontally and vertically adjacent pairs generally exhibiting the tightest process matching due to their smaller separation distance.

In an example, a memory die at a wafer location that does not have a suitable adjacent pair, such as the die location identified by reference numeral 453 at the edge of the wafer 450 in FIG. 4, where one side of the die abuts the wafer boundary rather than another die location. This may be used as a standard wider-width memory device rather than as a component of the apparatus 300. Similarly, if the adjacent candidate pair for a given die location fails electrical testing or exhibits a tWCK2DQO mismatch exceeding the predetermined tolerance, that die may be redirected to use in a standard device configuration. The x6 memory devices intended for use in the apparatus 300 may therefore be a subset of the total die population on the wafer 450, with unpaired or mismatched dies contributing to the standard device population. This selective pairing approach can be expected to yield sufficient quantities of matched device pairs for the apparatus 300 given that the x6 device configuration is a specialized capacity variant rather than a high-volume mainstream product.

In an example, the first and second memory devices are further characterized by matched delay sensitivity to at least one of temperature variation and supply voltage variation. While the absolute tWCK2DQO delay matching described above can address the inter-device delay difference at a fixed operating condition, the delay sensitivity matching can address the rate at which each device's tWCK2DQO delay changes in response to temperature or supply voltage excursions during normal operation. If the two devices have different delay sensitivities, the inter-device mismatch will grow as the operating temperature rises, potentially exceeding the compensation range of the timing compensation circuitry at elevated temperatures even if the mismatch was within tolerance at the initial operating condition. For example, if the tWCK2DQO of the first memory device increases more rapidly with temperature than that of the second memory device, this corresponds to different delay sensitivities. Delay sensitivity matching may be assessed by measuring the tWCK2DQO delay of each candidate device at two or more temperature points, for example at 25°C and 85°C, and comparing the rate of change between candidate pairs, selecting pairs whose delay sensitivity values are mutually matched within an acceptable range. The adjacent-die pairing strategy described above inherently provides a degree of delay sensitivity matching in addition to absolute delay matching, because the process characteristics that determine the absolute delay also largely determine the delay sensitivity, and spatially proximate dies share these characteristics due to the spatial correlation of process variation.

In an example, the first and second memory devices are disposed in a vertically stacked arrangement within a common package. The vertical stacking of the first memory device including rank dies 351A and 351B and the second memory device including rank dies 352A and 352B within a common package places the two devices in close physical proximity, such that both devices share substantially the same thermal environment and experience nearly identical temperature and supply voltage conditions during operation. The shared thermal environment means that any temperature-induced drift in the tWCK2DQO delay of one device is closely tracked by a corresponding drift in the other device, so that the inter-device tWCK2DQO mismatch remains small even as the absolute delay of each device changes with temperature.

Additionally, the two memory devices receive identical command and address traffic over the shared CA[3:0], CLK, and CS[1:0] bus of the apparatus 300 illustrated in FIG. 3, causing both devices to execute the same operations simultaneously and therefore generate correlated self-heating and supply current draw. Simulations of the vertically stacked package configuration can confirm that this combination of tight thermal coupling and correlated electrical activity produces excellent voltage and temperature tracking between the two devices, significantly reducing the dynamic component of the inter-device tWCK2DQO mismatch during normal operation. Combined with the initial absolute delay matching achieved through adjacent-die pairing and delay measurement circuit-based selection, the vertically stacked package arrangement ensures that the inter-device mismatch remains well within the plus or minus two unit interval compensation range of the timing compensation circuitry across the full operating lifetime of the apparatus 300.

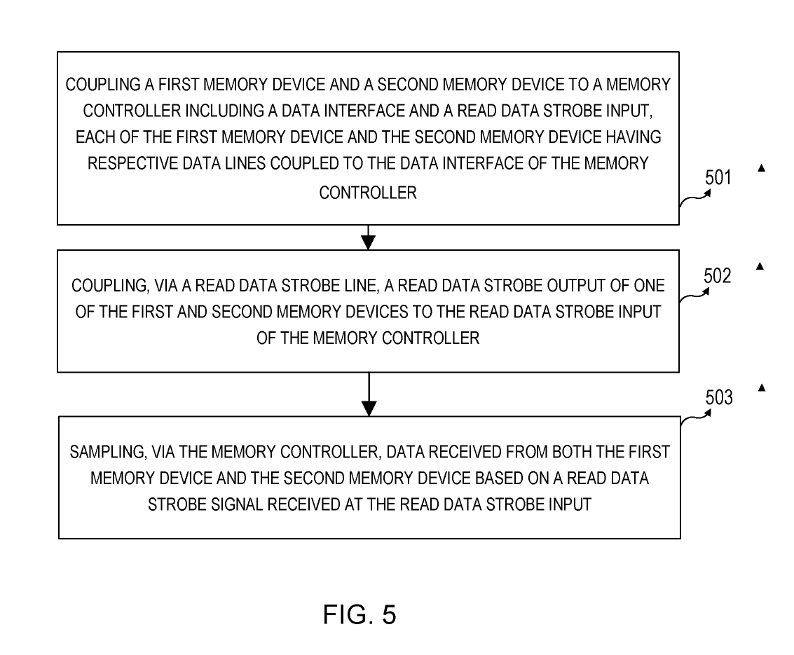

FIG. 5 shows an example of a method. The method may include: coupling 501 a first memory device and a second memory device to a memory controller including a data interface and a read data strobe input, each of the first memory device and the second memory device having respective data lines coupled to the data interface of the memory controller; coupling 502, via a read data strobe line, a read data strobe output of one of the first and second memory devices to the read data strobe input of the memory controller; and sampling 503, via the memory controller, data received from both the first memory device and the second memory device based on a read data strobe signal received at the read data strobe input.

The detailed description refers to the accompanying drawings that show, by way of illustration, specific details and aspects of this disclosure in which the disclosure may be practiced. Other aspects may be utilized and structural, logical, and electrical changes may be made without departing from the scope of the disclosure. The various aspects of this disclosure are not necessarily mutually exclusive, as some aspects of this disclosure can be combined with one or more other aspects of this disclosure to form new aspects.

Throughout the drawings, it should be noted that like reference numbers are used to depict the same or similar elements, features, and structures, unless otherwise noted.

The word "exemplary" is used herein to mean "serving as an example, instance, or illustration". Any aspect or design described herein as "exemplary" is not necessarily to be construed as preferred or advantageous over other aspects or designs.

The phrase “at least one” and “one or more” may be understood to include a numerical quantity greater than or equal to one (e.g., one, two, three, four, […], etc.). The phrase "at least one of" with regard to a group of elements may be used herein to mean at least one element from the group consisting of the elements. For example, the phrase "at least one of" with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, […], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

Further, spatially relative terms, such as "beneath," "below," "lower," "above," "upper" and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, unless otherwise specified the use of the ordinal adjectives “first”, “second”, “third” etc., to describe a common object, merely indicate that different instances of like objects are being referred to, and are not intended to imply that the objects so described must be in a given sequence, either temporally, spatially, in ranking, or in any other manner.

As utilized herein, terms "module", "component," "system," "circuit," "element," "slice," "circuitry," and the like are intended to refer to a set of one or more electronic components, a computer-related entity, hardware, software (e.g., in execution), and/or firmware. For example, circuitry or a similar term can be a processor, a process running on a processor, a controller, an object, an executable program, a storage device, and/or a computer with a processing device. By way of illustration, an application running on a server and the server can also be circuitry. One or more circuits can reside within the same circuitry, and circuitry can be localized on one computer and/or distributed between two or more computers. A set of elements or a set of other circuits can be described herein, in which the term "set" can be interpreted as "one or more."

It will be understood that when an element is referred to as being "connected" or "coupled" to another element, it can be physically connected or coupled to the other element such that current and/or electromagnetic radiation (e.g., a signal) can flow along a conductive path formed by the elements. Intervening conductive, inductive, or capacitive elements may be present between the element and the other element when the elements are described as being coupled or connected to one another. Further, when coupled or connected to one another, one element may be capable of inducing a voltage or current flow or propagation of an electro-magnetic wave in the other element without physical contact or intervening components. Further, when a voltage, current, or signal is referred to as being "applied" to an element, the voltage, current, or signal may be conducted to the element by way of a physical connection or by way of capacitive, electro-magnetic, or inductive coupling that does not involve a physical connection.

The following examples pertain to further aspects of this disclosure.

Example 1 includes the subject matter of an apparatus. The apparatus including: a memory controller including a data interface and a read data strobe input; a first memory device and a second memory device, each having respective data lines coupled to the data interface of the memory controller; and a read data strobe line coupling a read data strobe output of one of the first and second memory devices to the read data strobe input of the memory controller, wherein the memory controller is configured to sample data received from both the first memory device and the second memory device based on a read data strobe signal received at the read data strobe input.

Example 2 may include the subject matter of example 1, wherein each of the first and second memory devices is configured to output read data on its respective data lines in temporal relation to a clock signal received from the memory controller.

Example 3 may include the subject matter of any one of examples 1 to 2, wherein the memory controller is configured to be unresponsive to a read data strobe output of the other of the first and second memory devices.

Example 4 may include the subject matter of example 3, wherein the read data strobe output of the other of the first and second memory devices is electrically disconnected from the read data strobe input of the memory controller.

Example 5 may include the subject matter of any one of examples 1 to 4, wherein the memory controller further includes timing compensation circuitry configured to compensate for a difference in signal propagation delay between the first memory device and the second memory device.

Example 6 may include the subject matter of example 5, wherein the timing compensation circuitry is configured to apply a respective sampling timing offset for data received from each of the first and second memory devices relative to the read data strobe signal.

Example 7 may include the subject matter of example 6, wherein the respective sampling timing offset is bounded by a predetermined maximum number of unit intervals of a data clock signal.

Example 8 may include the subject matter of any one of examples 6 to 7, wherein the timing compensation circuitry is configured to select, for each of the first and second memory devices, a respective sampling edge polarity and a respective phase delay for sampling data received from that memory device.

Example 9 may include the subject matter of any one of examples 5 to 8, wherein the timing offset is determined by a training procedure executed during initialization of the apparatus, wherein the training procedure includes a sweep across a plurality of candidate timing offset values and selection of a timing offset value based on data validity detected during the sweep.

Example 10 may include the subject matter of any one of examples 1 to 9, may further include a write clock line coupling a write clock output of the memory controller to clock inputs of both the first and second memory devices, wherein each of the first and second memory devices has a data interface with a data width narrower than a data width of the data interface of the memory controller.

Example 11 may include the subject matter of any one of examples 1 to 10, may further include a write clock line coupling a write clock output of the memory controller to clock inputs of both the first and second memory devices.

Example 12 may include the subject matter of example 11, wherein the signal trace has an impedance transition at a branch point where the signal trace divides toward the first and second memory devices.

Example 13 may include the subject matter of any one of examples 1 to 12, wherein the first and second memory devices have mutually matched internal signal propagation delays, the delays being matched to within a predetermined number of unit intervals of a data clock signal.

Example 14 may include the subject matter of any one of examples 1 to 12, wherein the first and second memory devices have mutually matched internal signal propagation delays, the delays being matched to within a predetermined number of unit intervals of a data clock signal.

Example 15 may include the subject matter of any one of examples 13 to 14, wherein each of the first and second memory devices includes a delay measurement circuit configured to generate a timing signal representative of the respective internal signal propagation delay, and wherein the matched delays are based on respective timing signals generated by the delay measurement circuits of the first and second memory devices.

Example 16 may include the subject matter of any one of examples 13 to 15, wherein the first and second memory devices are from adjacent die locations on a common semiconductor wafer.

Example 17 may include the subject matter of any one of examples 13 to 16, wherein the first and second memory devices are further characterized by matched delay sensitivity to at least one of temperature variation and supply voltage variation.

Example 18 may include the subject matter of any one of examples 1 to 17, wherein the first and second memory devices are disposed in a vertically stacked arrangement within a common package.

Example 19 may include the subject matter of any one of examples 1 to 18, wherein each of the first and second memory devices includes a plurality of ranks independently addressable by the memory controller.

Example 20 may include the subject matter of any one of examples 1 to 19, wherein the data lines of the first memory device are coupled to a first portion of the data interface and the data lines of the second memory device are coupled to a second, different portion of the data interface.

Example 21 may include the subject matter of example 20, wherein a data width of each of the first and second memory devices is half of a data width of the data interface of the memory controller.

Example 22 may include the subject matter of a method including: coupling a first memory device and a second memory device to a memory controller including a data interface and a read data strobe input, each of the first memory device and the second memory device having respective data lines coupled to the data interface of the memory controller; coupling, via a read data strobe line, a read data strobe output of one of the first and second memory devices to the read data strobe input of the memory controller; and sampling, via the memory controller, data received from both the first memory device and the second memory device based on a read data strobe signal received at the read data strobe input.

Example 23 may include the subject matter of example 22, further includes outputting, by each of the first and second memory devices, read data on its respective data lines in temporal relation to a clock signal received from the memory controller.

Example 24 may include the subject matter of any one of examples 22 to 23, wherein the memory controller is unresponsive to a read data strobe output of the other of the first and second memory devices.

Example 25 may include the subject matter of example 24, wherein the read data strobe output of the other of the first and second memory devices is electrically disconnected from the read data strobe input of the memory controller.

Example 26 may include the subject matter of any one of examples 22 to 25, may further include compensating, by timing compensation circuitry of the memory controller, for a difference in signal propagation delay between the first memory device and the second memory device.

Example 27 may include the subject matter of example 26, may further include applying, by the timing compensation circuitry, a respective sampling timing offset for data received from each of the first and second memory devices relative to the read data strobe signal.

Example 28 may include the subject matter of example 27, wherein the respective sampling timing offset is bounded by a predetermined maximum number of unit intervals of a data clock signal.

Example 29 may include the subject matter of any one of examples 27 to 28, may further include selecting, by the timing compensation circuitry and for each of the first and second memory devices, a respective sampling edge polarity and a respective phase delay for sampling data received from that memory device.

Example 30 may include the subject matter of any one of examples 26 to 29, wherein the timing offset is determined by a training procedure executed during initialization of the apparatus, wherein the training procedure includes a sweep across a plurality of candidate timing offset values and selection of a timing offset value based on data validity detected during the sweep.

Example 31 may include the subject matter of any one of examples 22 to 30, may further include coupling, by a write clock line, a write clock output of the memory controller to clock inputs of both the first and second memory devices, wherein each of the first and second memory devices has a data interface with a data width narrower than a data width of the data interface of the memory controller.

Example 32 may include the subject matter of any one of examples 22 to 31, may further include coupling, by a write clock line, a write clock output of the memory controller to clock inputs of both the first and second memory devices.

Example 33 may include the subject matter of example 32, wherein the signal trace has an impedance transition at a branch point where the signal trace divides toward the first and second memory devices.

Example 34 may include the subject matter of any one of examples 22 to 33, wherein the first and second memory devices have mutually matched internal signal propagation delays, the delays being matched to within a predetermined number of unit intervals of a data clock signal.

Example 35 may include the subject matter of any one of examples 22 to 34, may further include generating, by a delay measurement circuit of each of the first and second memory devices, a timing signal representative of the respective internal signal propagation delay, and wherein matched delays are based on respective timing signals generated by the delay measurement circuits of the first and second memory devices.

Example 36 may include the subject matter of any one of examples 34 to 35, wherein the first and second memory devices are from adjacent die locations on a common semiconductor wafer.

Example 37 may include the subject matter of any one of examples 34 to 36, wherein the first and second memory devices are further characterized by matched delay sensitivity to at least one of temperature variation and supply voltage variation.

Example 38 may include the subject matter of any one of examples 22 to 37, wherein the first and second memory devices are disposed in a vertically stacked arrangement within a common package.

Example 39 may include the subject matter of any one of examples 22 to 38, wherein each of the first and second memory devices includes a plurality of ranks independently addressable by the memory controller.

Example 40 may include the subject matter of any one of examples 22 to 39, wherein the data lines of the first memory device are coupled to a first portion of the data interface and the data lines of the second memory device are coupled to a second, different portion of the data interface.

Example 41 may include the subject matter of example 40, wherein a data width of each of the first and second memory devices is half of a data width of the data interface of the memory controller.

Example 42 may include an apparatus including means to perform the methods of any one of examples 22 to 41.

What is claimed is:

1. An apparatus comprising:
a memory controller comprising a data interface and a read data strobe input;
a first memory device and a second memory device, each having respective data lines coupled to the data interface of the memory controller; and
a read data strobe line coupling a read data strobe output of one of the first and second memory devices to the read data strobe input of the memory controller, wherein the memory controller is configured to sample data received from both the first memory device and the second memory device based on a read data strobe signal received at the read data strobe input.

2. The apparatus of claim 1, wherein each of the first and second memory devices is configured to output read data on its respective data lines in temporal relation to a clock signal received from the memory controller.

3. The apparatus of claim 1, wherein the memory controller is configured to be unresponsive to a read data strobe output of the other of the first and second memory devices.

4. The apparatus of claim 3, wherein the read data strobe output of the other of the first and second memory devices is electrically disconnected from the read data strobe input of the memory controller.

5. The apparatus of claim 1, wherein the memory controller further comprises timing compensation circuitry configured to compensate for a difference in signal propagation delay between the first memory device and the second memory device.

6. The apparatus of claim 5, wherein the timing compensation circuitry is configured to apply a respective sampling timing offset for data received from each of the first and second memory devices relative to the read data strobe signal.

7. The apparatus of claim 6, wherein the respective sampling timing offset is bounded by a predetermined maximum number of unit intervals of a data clock signal.

8. The apparatus of claim 6, wherein the timing compensation circuitry is configured to select, for each of the first and second memory devices, a respective sampling edge polarity and a respective phase delay for sampling data received from that memory device.

9. The apparatus of claim 5, wherein the timing offset is determined by a training procedure executed during initialization of the apparatus, wherein the training procedure comprises a sweep across a plurality of candidate timing offset values and selection of a timing offset value based on data validity detected during the sweep.

10. The apparatus of claim 1, further comprising a write clock line coupling a write clock output of the memory controller to clock inputs of both the first and second memory devices, wherein each of the first and second memory devices has a data interface with a data width narrower than a data width of the data interface of the memory controller.

11. The apparatus of claim 1, further comprising a write clock line coupling a write clock output of the memory controller to clock inputs of both the first and second memory devices.

12. The apparatus of claim 11, wherein the signal trace has an impedance transition at a branch point where the signal trace divides toward the first and second memory devices.

13. The apparatus of claim 1, wherein the first and second memory devices have mutually matched internal signal propagation delays, the delays being matched to within a predetermined number of unit intervals of a data clock signal.

14. The apparatus of claim 13, wherein each of the first and second memory devices comprises a delay measurement circuit configured to generate a timing signal representative of the respective internal signal propagation delay, and wherein the matched delays are based on respective timing signals generated by the delay measurement circuits of the first and second memory devices.

15. The apparatus of claim 13, wherein the first and second memory devices are from adjacent die locations on a common semiconductor wafer.

16. The apparatus of claim 13, wherein the first and second memory devices are further characterized by matched delay sensitivity to at least one of temperature variation and supply voltage variation.

17. The apparatus of claim 1, wherein the first and second memory devices are disposed in a vertically stacked arrangement within a common package.

18. The apparatus of claim 1, wherein each of the first and second memory devices comprises a plurality of ranks independently addressable by the memory controller.

19. A method comprising:
coupling a first memory device and a second memory device to a memory controller comprising a data interface and a read data strobe input, each of the first memory device and the second memory device having respective data lines coupled to the data interface of the memory controller;
coupling, via a read data strobe line, a read data strobe output of one of the first and second memory devices to the read data strobe input of the memory controller; and sampling, via the memory controller, data received from both the first memory device and the second memory device based on a read data strobe signal received at the read data strobe input.

20. The method of claim 19, further comprises outputting, by each of the first and second memory devices, read data on its respective data lines in temporal relation to a clock signal received from the memory controller.
